(19) United States
(12) Patent Application Publication
(10) Pub. No.: US 2023/0251292 A1
(43) Pub. Date: Aug. 10, 2023

(54) DATA ANALYSIS SYSTEM, MEASUREMENT DEVICE, AND METHOD

(71) Applicant: ROHDE & SCHWARZ GMBH & CO. KG, München (DE)

(72) Inventors: Andreas RITTER, München (DE); Klaus FOERTSCHBECK, München (DE)

(21) Appl. No.: 17/667,248

(22) Filed: Feb. 8, 2022

(51) Int. Cl. G01R 23/16; G06F 3/14

(52) U.S. Cl. CPC G01R 23/16; G06F 3/14

(57) ABSTRACT

A data analysis system includes a data input interface for receiving a time domain signal, a data segmentation processor that segments the time domain signal into single segments of a predetermined length, a data converter that converts the time domain signal into a spectrum waveform in the frequency domain based on the single segments, a data analyzer that detects a data anomaly in the spectrum waveform, a segment identifier that, if the data anomaly is detected in the spectrum waveform, identifies the segment that causes the data anomaly in the spectrum waveform, and a data output interface that, if the data anomaly is detected in the spectrum waveform, outputs at least one of an indication of the identified segment and the identified segment. The present disclosure further provides a respective measurement device and a respective method.

### TECHNICAL FIELD

The disclosure relates to a data analysis system, a measurement device, and a method.

### BACKGROUND

Although applicable to any time series of data, the present disclosure will mainly be described in conjunction with measured time series of data that represent a signal measured or acquired in a device under test.

When developing electrical systems, signals are usually measured in a respective device under test to verify the correct functionality of the respective device. Other situations may exist, where signals need to be measured in the field after a device is installed to identify sources of errors in the system.

Signals are measured in the time domain and usually, a user visually inspects the signals in the time domain. However, in the time domain erroneous signal components may be difficult to identify.

Accordingly, there is a need for improving signal analysis.

### SUMMARY

The above stated problem is solved by the features of the independent claims. It is understood, that independent claims of a claim category may be formed in analogy to the dependent claims of another claim category.

Accordingly, it is provided:

A data analysis system comprising a data input interface for receiving a time domain signal, the time domain signal consisting e.g., of a time series of data points, a data segmentation processor that segments the time domain signal into single segments of a predetermined length, a data converter that converts the time domain signal into a spectrum waveform in the frequency domain based on the single segments, a data analyzer that detects a data anomaly in the spectrum waveform, a segment identifier that, if the data anomaly is detected in the spectrum waveform, identifies the segment that causes the data anomaly in the spectrum waveform, and a data output interface that, if the data anomaly is detected in the spectrum waveform, outputs at least one of an indication of the identified segment and the identified segment.

Further, it is provided:

A measurement device comprising a measurement interface that measures a time series of data points, a generator that generates a time domain signal from the time series of data points, a data analysis system comprising: a data input interface for receiving the time domain signal, a data segmentation processor that segments the time domain signal into single segments of a predetermined length, a data converter that converts the time domain signal into a spectrum waveform in the frequency domain based on the single segments, a data analyzer that detects a data anomaly in the spectrum waveform, a segment identifier that, if the data anomaly is detected in the spectrum waveform, identifies the segment that causes the data anomaly in the spectrum waveform, and a data output interface that, if the data anomaly is detected in the spectrum waveform, outputs at least one of an indication of the identified segment and the identified segment; and a display that displays at least one of the time domain signal and the spectrum waveform, and, if the data anomaly is detected in the spectrum waveform, further displays the detected segment as alternative to the time domain signal or in addition to the time domain signal.

Further, it is provided:

A data analysis method comprising receiving a time domain signal, segmenting the time domain signal into single segments of a predetermined length, converting the time domain signal into a spectrum waveform in the frequency domain based on the single segments, detecting a data anomaly in the spectrum waveform, if the data anomaly is detected in the spectrum waveform, identifying the segment that causes the data anomaly in the spectrum waveform, and if the data anomaly is detected in the spectrum waveform, outputting at least one of an indication of the identified segment and the identified segment.

The present disclosure is based on the finding that anomalies in a signal are often easily detected in the signal in the frequency domain, while it may be hard to detect such an anomaly in the signal in the time domain.

However, for a user after converting a signal from the time domain into the frequency domain, no visual link between the position of a signal component in the time domain and the frequency domain exists. For the user it is therefore impossible to determine the exact position of the signal anomaly in the time domain after identifying a signal anomaly in the frequency domain signal.

The present disclosure provides such a link between a signal anomaly that may be detected in the frequency domain and the signal component in the time domain that causes the signal anomaly.

To this end, the data analysis system comprises a data input interface that receives a time domain signal. It is understood, that the time domain signal may be received in digital form as digital data. Such a time domain signal may be measured or recorded for analysis by the data analysis system e.g., by a measurement device according to the present disclosure. The data input interface may for example be provided as a hardware interface, like a network interface, or a bus interface. In an embodiment, the data input interface may also comprise a measurement interface of a measurement device and acquire the time domain signal from a device under test, DUT.

The received time domain signal is provided to the data segmentation processor that segments the time domain signal into single consecutive segments of a predetermined length. In embodiments, the data segmentation processor may generate at least two or more segments.

The data converter then converts the single segments into the frequency domain to provide a spectrum waveform of the time domain signal in the frequency domain. For example, a Fourier Transform, especially a Fast Fourier Transform, or the like may be applied. Generally, the data converter may convert the single segments into the frequency domain segments and generate the full spectrum waveform for the time domain signal by summing up, adding or overlaying the frequency domain segments. In an embodiment, the transformation may for example be performed as described in “Performing Fourier transforms on extremely long data streams” by W.K. Hocking in “Computers in Physics 3, 59 (1989)”, https://doi.org/10.1063/1.168338, which is included herein by reference.

The data analyzer will analyze the spectrum waveform to identify a data anomaly in the spectrum waveform. The data anomaly may be any kind of anomaly that may be defined e.g., by a user or may be selected from a predefined list of anomalies.

For example, an anomaly database may be provided that comprises definitions of different data anomalies. The database may for example comprise definitions that are structured or grouped according to different sources of the time domain signal. The definitions may for example be grouped by communication standards or communication systems in the anomaly database. The anomaly database may for example be provided in the data analysis system or as an external database that may for example be accessible via a data network.

A data anomaly may for example refer to a predefined area or a zone in the frequency diagram that shows the spectrum waveform. If a signal component in such a zone is detected in the spectrum waveform, the data analyzer may indicate that a data anomaly is detected.

If the data anomaly is defined by a user, the user may for example define such a zone graphically in the frequency diagram e.g., by drawing a box, a rectangle, a square or another shape.

Of course, multiple such zones may form the definition of a data anomaly. It is understood, that multiple zones may be combined by logical operators, like AND, OR, XOR, and the like, to define a data anomaly.

In case that the data analyzer identifies a data anomaly, the segment identifier identifies the respective segment of the time domain signal that caused the data anomaly and provides a respective indication.

The data output interface will then output the indication or the identified segment or both.

The information about the identified segment may then for example be used to show the respective segment to a user.

If the data analysis system is integrated in a measurement device, like an oscilloscope, the respective segment may be shown to the user of the measurement device on the screen of the measurement device.

According to the present disclosure different implementations of the data analysis system are possible.

The data analysis system and the single elements of the data analysis system i.e., the data input interface, the data output interface, the data segmentation processor, the data converter, the data analyzer, and the segment identifier may e.g., be provided as a dedicated processing element or implemented in such a dedicated processing element, like e.g., a processing unit, a microcontroller, an FPGA, a CPLD or the like. Such a dedicated processing element may comprise a processing unit coupled to an internal or external memory that holds respective computer executable instructions that may be executed by the processing unit.

In addition, it is understood, that any required supporting or additional hardware may be provided like e.g., a power supply circuitry and clock generation circuitry.

The data analysis system and its elements may at least in part be provided as a computer program product comprising computer readable instructions that may be executed by a processing element. As indicated above, such computer readable instructions may be stored in a memory that is coupled to a respective processing element.

In a further embodiment, the data analysis system may be provided as addition or additional function or method to the firmware or operating system of a processing element that is already present in the respective application, like a measurement device.

In case the data analysis system is provided as computer program product comprising the respective computer readable instructions, the data input interface and the data output interface may comprise an API or respective callable functions that perform the functions of the data input interface and the data output interface.

The data segmentation processor, the data converter, the data analyzer and the segment identifier may be provided as respective functions or as a single function that processes the time domain signal and detects data anomalies and identifies the respective segment.

In case that the data analysis system is integrated in a measurement device, the data analysis system may be implemented as an additional function or additional functions in the operating software of the measurement device. A user may for example select the data analysis system via the user interface of the measurement device and the data analysis system may then be executed within the measurement device and may be applied to a respective time domain signal.

With the data analysis system or measurement device of the present disclosure a user may easily identify the source of an anomaly in a signal in the frequency domain and directly visualize the respective section of the time domain signal to continue the error analysis.

Further embodiments of the present disclosure are subject of the further dependent claims and of the following description, referring to the drawings.

In an embodiment, the time domain signal may comprise at least one of a real value time series of data points, a signal that is derived from a real value time series of data points, an envelope of a signal in the time domain, a complex value time series of data points, a mathematical derivative of a real value time series of data points, a logarithm of a real value time series of data points, a n-th root of a real value time series of data points, a maximum function of a real value time series of data points, a minimum function of a real value time series of data points, and an average function of a real value time series of data points.

The time domain signal may be any type of signal in the time domain. Such a signal may be a measured or acquired signal, that may be measured or acquired with a measurement device.

The time domain signal may also be derived from a measured signal or a time series that represents a measured signal. Deriving in this context may for example refer to calculating an envelope of a signal in the time domain. The term “envelope” in this context refers to the envelope of the time series of data points that represent the measured signal. Calculating the envelope is also known as “envelope tracking”.

The time domain signal may also comprise a complex value time series of data points, like for example IQ data points that are derived from a or calculated based on a measured signal.

Further, the time domain signal may comprise a logarithm of a real value time series of data points, or a n-th root of a real value time series of data points. The respective function may be applied to the single data points to calculate the time domain signal.

In addition, the time domain signal may comprise a mathematical derivative of a real value time series of data points, or a maximum function of a real value time series of data points, a minimum function of a real value time series of data points, and an average function of a real value time series of data points. It is understood, that the respective function may be applied to a subset of samples or data points of the respective time series of data points. This means that a kind of window may be applied to calculate the single data points of the time domain signal. The size of the single subsets may e.g., be equal to or be based on the size of the segments that are generated by the data converter.

In yet another embodiment, the data segmentation processor may segment the time domain signal such that consecutive ones of the single segments comprise an overlap of a predetermined amount with each other.

A Fourier Transform, especially a Fast Fourier Transform, is usually performed with a window function that is applied to the signal to be analyzed. Usually this window function will result in the signal levels at the edges of the window being reduced towards zero. Therefore, an overlap of the single segments may be provided such that no signal component at the edges of the single segments is neglected in the analysis.

In another embodiment, the data input interface may receive a stored time domain signal.

The time domain signal as indicated above may be measured by a measurement device and stored in a memory of the measurement device.

In an embodiment, the measurement device may only store segments of measured data in the memory. Such stored segments of measured data may correspond to the segments of the time domain signal that are processed by the data converter. In such an example, the data segmentation processor may simply pass the respective stored segments to the data converter.

A measurement device, like an oscilloscope, may store only segments of measured data when operated in a specific mode of operation. Such a mode of operation may also be called “segmented memory data acquisition” mode. In this mode, the measurement device may use its limited memory to only record the relevant sections or active periods of a signal.

For example, in a bus system, when no signal is actively transmitted, the bus level may be zero for a long period of time. Continuously acquiring the signal and storing the respective measurement data in the memory of the measurement device may quickly fill up the memory without acquiring a lot of useful data.

In the “segmented memory data acquisition” mode, the measurement device may therefore use a trigger that is activated when an active signal is present on the bus system and store the acquired signal from a predetermined time before the trigger is activated until a predetermined time after the trigger is activated, e.g., for the duration of a data packet in the bus system plus a predefined margin.

The memory of the measurement device, when operating in the “segmented memory data acquisition” mode, is therefore only filled with relevant data that represents the active signaling periods in the bus system.

In embodiments, the time domain signal may also be stored in a memory that is not part of the measurement device or that is not provided in the same device as the data analysis system, like a database or the like.

The data analysis system may, consequently, also be used as a standalone system that may for example be provided as a service that is accessible via a data network. Such a service may for example expose a respective user interface, like a website, or respective APIs or endpoints that allow a user or an application to provide the time domain signal to the data analysis system and to retrieve the at least one of an indication of the identified segment or the identified segment from the data output interface.

In a further embodiment, the segment identifier may further identify a time stamp of the identified segment. In addition, the data output interface may further output the time stamp with the at least one of an indication of the identified segment or the identified segment or may output the time stamp instead of the at least one of an indication of the identified segment or the identified segment.

Providing a time stamp of the identified segment allows matching or correlating the position of the anomaly in the time domain signal with other signals. Such other signals may for example be signals that are measured alongside the signal that forms the basis for the time domain signal, which may be the case in complex measurement applications, where multiple signals are measured at the same time. The other signals may then also be analyzed for any anomalies at the respective point in time. Causes of the anomalies that propagate via various sources or signals may therefore be easily identified.

In an embodiment, the data analysis system may comprise a display that displays at least one of the time domain signal and the spectrum waveform.

The display may be coupled to different elements of the data analysis system, like for example to the data input interface for displaying the time domain signal, to the data converter for displaying the spectrum waveform, and to the segment identifier or the data output interface for displaying the identified segment.

It is understood, that the display may comprise a respective display controller and a display device. Such a display controller may comprise a hardware unit, like for example a respective display controller IC. In addition or as alternative, such a display controller may also comprise computer readable instructions that may be executed by a computing unit. The explanations provided above for the elements of the data analysis system in this regard also apply to the display.

The display controller may comprise the functionality of controlling the display device to draw the time domain signal and the spectrum waveform on the display device. Of course, the display controller may at least in part be integrated into other elements of a system that implements the data analysis system. Such a system may for example comprise a computer or a measurement device and the display device may be the screen of the computer or measurement device.

In yet another embodiment, if the data anomaly is detected in the spectrum waveform, the display may display the detected segment as alternative to the time domain signal or in addition to the time domain signal.

The detected segment is a sub-section of the time domain signal. Therefore, the display may show the segment as soon as the anomaly is detected in addition or as alternative to the time domain signal. The identified segment may for example be magnified at least along the time axis and be shown below the time domain signal. Magnification along the second axis is also possible. Respective borders or lines may be drawn from the start point of the identified segment in the time domain signal to the start of the magnified segment, and from the end point of the identified segment in the time domain signal to the end of the magnified segment.

The spectrum waveform may be displayed below the time domain signal as long as no anomaly is detected. If an anomaly is detected, the respective segment may be displayed between the time domain signal and the spectrum waveform or below the spectrum waveform.

In another embodiment, the segment identifier may further identify the source of the anomaly in the respective segment of the time domain signal.

The anomaly in the spectrum waveform may for example comprise a signal peak at a specific frequency where no peak should be present. Such a peak may correspond to a runt signal i.e., to a positive signal section that has a lower amplitude than expected.

The segment identifier may identify such causes and indicate the cause in the time domain signal. The cause may for example be displayed horizontally centered in the display. The cause may also be marked with a color or a surrounding box.

Of course, the data output interface may also output this indication. In addition or as alternative, the display may also mark or indicate the cause in the display of the time domain signal.

In a further embodiment, the data analysis system may comprise an automatic anomaly identifier that defines the anomaly based on an analysis of the spectrum waveform, wherein the analysis comprises at least one of calculating an average value, calculating a mean value, and applying a machine learning algorithm.

The automatic anomaly identifier may e.g., be provided as a dedicated processing element or implemented in such a dedicated processing element, like e.g., a processing unit, a microcontroller, an FPGA, a CPLD or the like and the respective. Such a dedicated processing element may comprise a processing unit coupled to an internal or external memory that holds respective computer executable instructions that may be executed by the processing unit.

In addition, it is understood, that any required supporting or additional hardware may be provided like e.g., a power supply circuitry and clock generation circuitry.

The automatic anomaly identifier may at least in part be provided as a computer program product comprising computer readable instructions that may be executed by a processing element. As indicated above, such computer readable instructions may be stored in a memory that is coupled to a respective processing element. The explanations provided above for the data analysis system and the elements of the data analysis system also apply to the automatic anomaly identifier. Of course the automatic anomaly identifier may be implemented alongside the further elements of the data analysis system in the same hardware device.

The automatic anomaly identifier may for example define the above-mentioned zones automatically based on an analysis of the spectrum waveform. The automatic anomaly identifier may for example calculate an average or median of the spectrum waveform and define the zones as all frequencies with a predetermined distance from the average or median values and with a an amplitude that is higher than a predefined minimum amplitude.

In addition or as alternative, a machine learning algorithm may be trained to define a respective anomaly. Such a machine learning algorithm may be trained with training data for at least one specific communication system or standard. Of course multiple machine learning algorithms may be provided for different communication systems or standards.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a block diagram of an embodiment of a data analysis system according to the present disclosure;

FIG. 2 shows a block diagram of another embodiment of a data analysis system according to the present disclosure;

FIG. 3 shows a block diagram of an embodiment of a measurement device according to the present disclosure;

FIG. 4 shows a block diagram of an embodiment of an oscilloscope as a measurement device according to the present disclosure;

FIG. 5 shows a flow diagram of an embodiment of a data analysis method according to the present disclosure;

FIG. 6 shows a diagram of a time domain signal and a spectrum waveform; and

FIG. 7 shows another diagram of a time domain signal and a spectrum waveform.

In the figures like reference signs denote like elements unless stated otherwise.

### DETAILED DESCRIPTION OF THE DRAWINGS

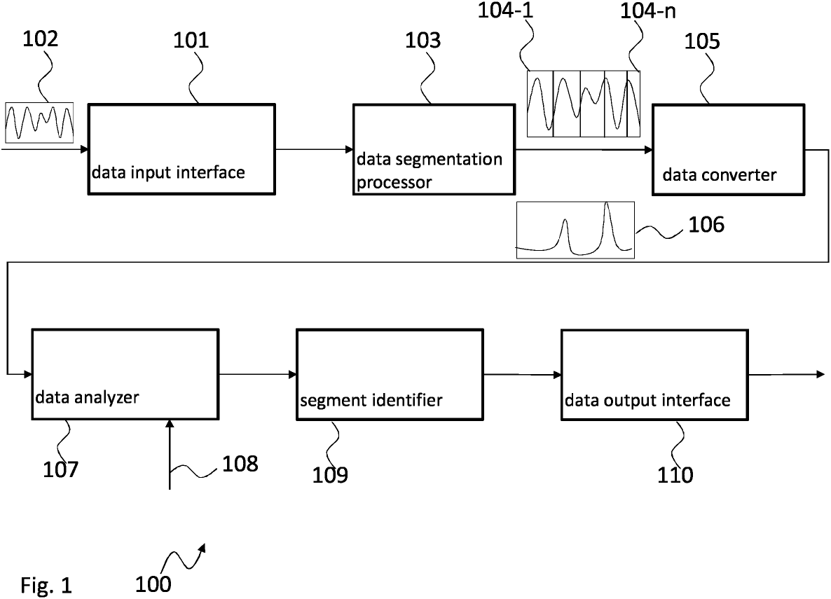

FIG. 1 shows a block diagram of a data analysis system 100. The data analysis system 100 comprises a data input interface 101 that is coupled to a data segmentation processor 103. The data segmentation processor 103 is coupled to a data converter 105 and the data converter 105 is coupled to a data analyzer 107. The data analyzer 107 is coupled to a segment identifier 109 that is coupled to a data output interface 110.

The data input interface 101 receives a time domain signal 102 and provides the time domain signal 102 to the data segmentation processor 103 that segments the time domain signal into single segments 104-1 - 104-n of a predetermined length. The segments 104-1 - 104-n are provided to the data converter 105 that converts the time domain signal 102 into a spectrum waveform 106 in the frequency domain based on the single segments 104-1 - 104-n.

The data analyzer 107 analyzes the spectrum waveform 106 and detects a data anomaly 108 in the spectrum waveform.

If the data anomaly 108 is detected in the spectrum waveform 106, the segment identifier 109 identifies the segment 104-1 - 104-n that causes the data anomaly in the spectrum waveform 106, and the data output interface 110 outputs at least one of an indication of the identified segment and the identified segment.

The data input interface 101 may be implemented as a function or API or a computer program that is made up of computer readable instructions and implements the function of the data analysis system 100 when the instructions are executed by a processing unit like a CPU. The data input interface 101 may at least in part also be implemented as a communication interface of e.g., a computer, for example as a network interface that receives the time domain signal 102 from a signal source. The same applies to the data output interface 110.

The data segmentation processor 103 may comprise a memory for storing one or multiple of the segments 104-1 - 104-n. In an embodiment, the data segmentation processor 103 may store the time domain signal 102 in the memory and only read the sections that correspond to a respective one of the segments 104-1 - 104-n from that memory for further processing. The data segmentation processor 103 may for example comprise a pointer to a start position of a segment in the memory and a counter for the length of the segment and read out as many data values of the time domain signal 102 as indicated by the counter starting from the position indicated by the pointer. After reading a full segment 104-1 - 104-n the pointer may be moved to the position of the value after the last data element of the respective segment 104-1 - 104-n and the next segment 104-1 - 104-n may be read from the memory. If an overlap is provided between the segments 104-1 - 104-n, the pointer may be positioned respectively i.e., pointing to a predetermined number of values before the last value of the segment 104-1 - 104-n that was read out.

The data converter 105 implements a Fourier Transform like e.g., a Fast Fourier Transform or FFT, and applies the FFT to the single segments 104-1 - 104-n. The FFT may be implemented as a software function that is executed by a processing element or as hardware-implemented FFT in a CPLD or FPGA or the like. Such a processing element, CPLD or FPGA may be coupled to the memory in which the data segmentation processor 103 stores the segments 104-1 - 104-n. Alternatively, the data converter 105 may also implement the function of the data segmentation processor 103, and to this end consecutively read respective sections that represent the data for a respective one of the segments 104-1 - 104-n from a memory that holds the full time domain signal 102.

In order to generate the spectrum waveform 106 the data converter 105 combines the single frequency domain segments after applying the FFT. The result is a spectrum waveform 106 for the full time domain signal 102.

The segment identifier 109 analyzes the spectrum waveform 106 to detect a predefined data anomaly 108 in the spectrum waveform 106. As indicated above, the data anomaly 108 may be user defined or may be loaded from a database. The data anomaly 108 may define one or multiple zones in the diagram of the spectrum waveform 106 that should not contain any signal component or that must contain a signal component. If the respective condition is not met, the data anomaly 108 may be detected.

Since the spectrum waveform 106 represents the full time domain signal 102 and is generated from multiple segments 104-1 - 104-n, each of the segments 104-1 - 104-n contributes a respective part to the spectrum waveform 106.

The segment identifier 109 may analyze, which of the segments 104-1 - 104-n contribute the signal component that fulfills the definition of the respective data anomaly 108. The segment identifier 109 may for example verify for every single one of the segments 104-1 -104-n if it contributes a respective signal component by analyzing the output of the data converter 105 for every single segment 104-1 - 104-n. The data output interface 110 outputs a respective indication. The output of the data output interface 110 may comprise the identified segment 104-1 - 104-n and/or an indication of the position of the identified segment 104-1 -104-n in the time domain signal 102.

If the segment identifier 109 identifies multiple segments 104-1 - 104-n that contribute a respective signal component, the output of the data output interface 110 may indicate accordingly.

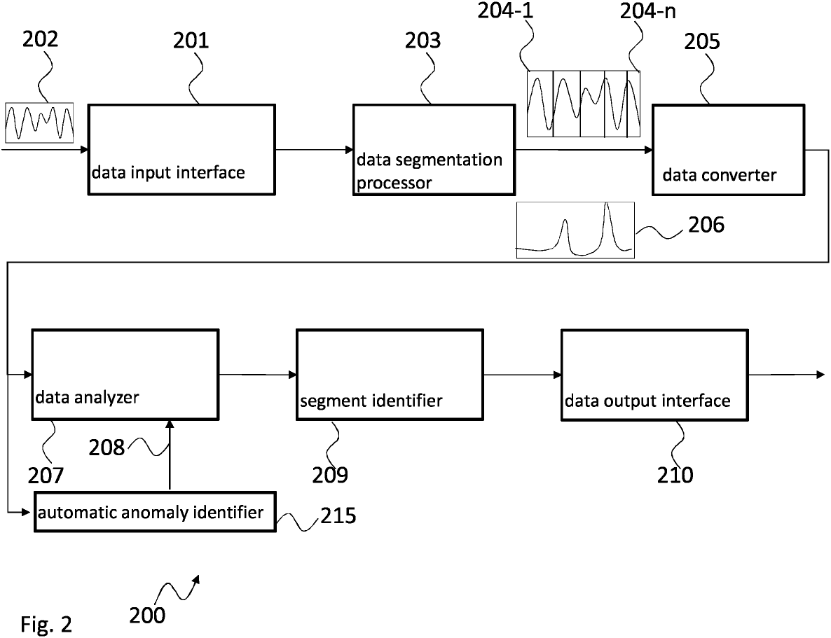

FIG. 2 shows a block diagram of a data analysis system 200. The data analysis system 200 is based on the data analysis system 100. Consequently, the data analysis system 200 comprises a data input interface 201 that is coupled to a data segmentation processor 203. The data segmentation processor 203 is coupled to a data converter 205 and the data converter 205 is coupled to a data analyzer 207. The data analyzer 207 is coupled to a segment identifier 209 that is coupled to a data output interface 210.

The above-presented explanations regarding the data analysis system 100 apply to the data analysis system 200 mutatis mutandis.

The data analysis system 200 further comprises an automatic anomaly identifier 215. The automatic anomaly identifier 215 receives the spectrum waveform 206 and calculates specific values or functions for the spectrum waveform 206. Such values or functions may be statistical values or functions, like for example an average value, a median value, a minimum or maximum value or any other relevant function or value.

Based on this calculation the automatic anomaly identifier 215 may define the data anomaly 208. For example, if an average or median frequency is determined for the spectrum waveform 206, at least one zone may be set for all frequencies below or above the average or median frequency, wherein a margin may be applied to the average or median frequency when defining the zones.

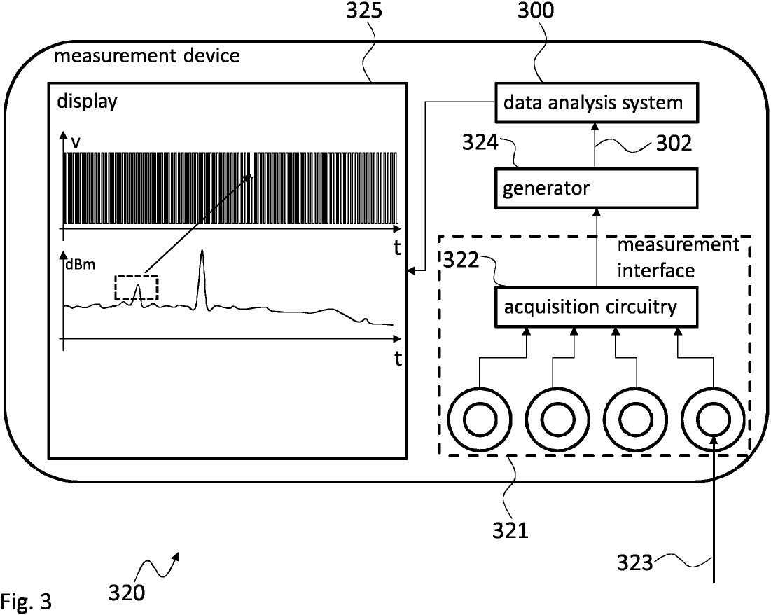

FIG. 3 shows a block diagram of a measurement device 320. The measurement device 320 comprises a measurement interface 321 that is coupled to a generator 324. The generator 324 is coupled to a data analysis system 300 and the data analysis system 300 is coupled to a display 325.

The measurement interface 321 comprises connectors for coupling the measurement device 320 to a device under test, DUT, for measuring a time series of data points 323 in the DUT. The measured signal or time series of data points 323 is provided to an acquisition circuitry 322 in the measurement interface 321. Such an acquisition circuitry 322 may e.g., comprise at least one of filters, amplifiers, attenuators, and analog-to-digital converters. The measurement interface 321 may be a measurement interface 321 as it is used in oscilloscopes for acquiring a signal.

The time series of data points 323 is provided to the generator 324. The generator 324 serves for converting the time series of data points 323 into the time domain signal 302 that is provided to the data analysis system 300. The generator 324 may for example provide the time series of data points 323 directly to the data analysis system 300 as time domain signal 102 without modifying the time series of data points 323.

The generator 324 may, however, calculate or derive the time domain signal 102 from the time series of data points 323. The generator 324 may for example calculate an envelope of a signal in the time domain, determine a complex value time series of data points, like for example IQ data points that are derived from a or calculated based on the time series of data points 323.

Further, the generator 324 may calculate a logarithm of, or a n-th root, or n-th power of the time series of data points 323. The respective function may be applied to the single data points of the time series of data points 323.

In addition, the generator 324 may calculate a mathematical derivative, or a maximum function, a minimum function, or an average function of the time series of data points 323.

The data analysis system 300 may be any type of data analysis system according to the present disclosure, for example a data analysis system 100 or data analysis system 200. The above-presented explanations regarding the data analysis system 100 and data analysis system 200 also apply to the data analysis system 300.

Although not explicitly shown, the measurement device 320 may comprise a display controller or the like that receives data from the data analysis system 300 for displaying on the display 325 and control the display 325 accordingly.

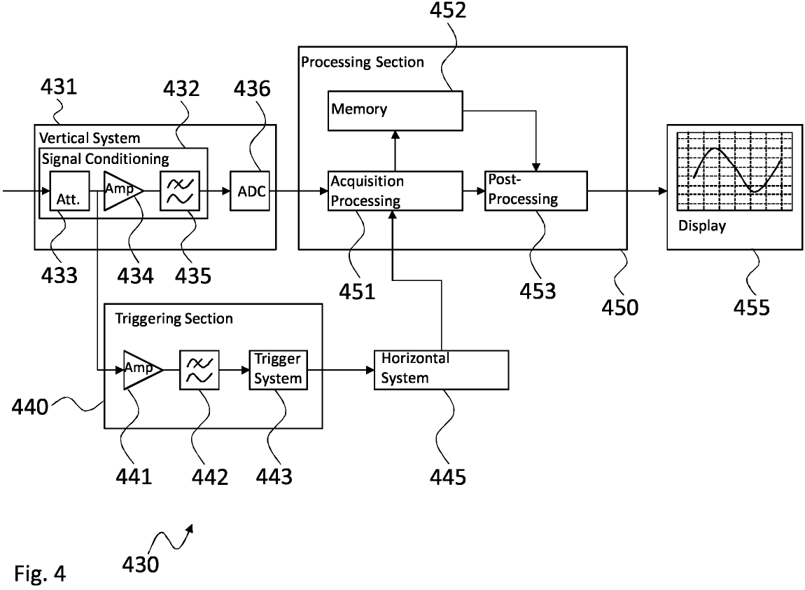

FIG. 4 shows a block diagram of an oscilloscope 430 that may be an implementation of a measurement device according to the present invention. The oscilloscope 430 is implemented as a digital oscilloscope. However, the present invention may also be implemented with any other type of oscilloscope.

The oscilloscope 430 exemplarily comprises five general sections, the vertical system 431, the triggering section 440, the horizontal system 445, the processing section 450 and the display 455. It is understood, that the partitioning into five general sections is a logical partitioning and does not limit the placement and implementation of any of the elements of the oscilloscope 430 in any way.

The vertical system 431 mainly serves for attenuating or amplifying a signal to be acquired. The signal may for example be modified to fit the signal in the available space on the display 455 or to comprise a vertical size as configured by a user.

To this end, the vertical system 431 comprises a signal conditioning section 432 with an attenuator 433 that is coupled to an amplifier 434. The amplifier 434 is coupled to a filter 435, which in the shown example is provided as a low pass filter. The vertical system 431 also comprises an analog-to-digital converter 436 that receives the output from the filter 435 and converts the received analog signal into a digital signal.

The attenuator 433 and the amplifier 434 serve to scale the waveform of the signal and to condition the amplitude of the signal to be acquired to match the operation range of the analog-to-digital converter 436. The filter 435 serves to filter out unwanted high frequency components of the signal to be acquired.

The triggering section 440 comprises an amplifier 441 that is coupled to a filter 442, which in this embodiment is implemented as a low pass filter. The filter 442 is coupled to a trigger system 443.

The triggering section 440 serves to capture predefined signal events and allows the horizontal system 445 to e.g., display a stable view of a repeating waveform, or to simply display waveform sections that comprise the respective signal event. It is understood, that the predefined signal event may be configured by a user via a user input of the oscilloscope 430.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

The triggering section 440 operates on the signal as provided by the attenuator 433, which is fed into the amplifier 441. The amplifier 441 serves to condition the input signal to the operating range of the trigger system 443. It is understood, that a common amplifier may also be used instead of the dedicated amplifiers 434 and 441.

In order to allow an exact matching of the trigger event and the waveform that is shown on the display 455, a common time base may be provided for the analog-to-digital converter 436 and the trigger system 443.

It is understood, that although not explicitly shown, the trigger system 443 may comprise at least one of <configurable voltage comparators for setting the trigger threshold voltage, fixed voltage sources for setting the required slope, respective logic gates like e.g., a XOR gate, and FlipFlops to generate the triggering signal.

The triggering section 440 is exemplarily provided as an analog trigger section. It is understood, that the oscilloscope 430 may also provided with a digital triggering section. Such a digital triggering section will not operate on the analog signal as provided by the attenuator 433 but will operate on the digital signal as provided by the analog-to-digital converter 436.

A digital triggering section may comprise a processing element, like a processor, a DSP, a CPLD or an FPGA to implement digital algorithms that detect a valid trigger event.

The horizontal system 445 is coupled to the output of the trigger system 443 and mainly serves to position and scale the signal to be acquired horizontally on the display 455.

The oscilloscope 430 further comprises a processing section 450 that implements digital signal processing and data storage for the oscilloscope 430. The processing section 450 comprises an acquisition processing element 451 that is couple to the output of the analog-to-digital converter 436 and the output of the horizontal system 445 as well as to a memory 452 and a post processing element 453.

The acquisition processing element 451 manages the acquisition of digital data from the analog-to-digital converter 436 and the storage of the data in the memory 452. The acquisition processing element 451 may for example comprise a processing element with a digital interface to the analog-to-digital converter 436 and a digital interface to the memory 452. The processing element may for example comprise a microcontroller, a DSP, a CPLD or an FPGA with respective interfaces. In a microcontroller or DSP the functionality of the acquisition processing element 451 may be implemented as computer readable instructions that are executed by a CPU. In a CPLD or FPGA the functionality of the acquisition processing element 451 may be configured in to the CPLD or FPGA.

The post processing element 453 may be controlled by the acquisition processing element 451 and may access the memory 452 to retrieve data that is to be displayed on the display 455. The post processing element 453 may condition the data stored in the memory 452 such that the display 455 may show the data e.g., as waveform to a user.

The display 455 controls all aspects of signal representation to a user, although not explicitly shown, may comprise any component that is required to receive data to be displayed and control a display device to display the data as required.

It is understood, that even if it is not shown, the oscilloscope 430 may also comprise a user interface for a user to interact with the oscilloscope 430. Such a user interface may comprise dedicated input elements like for example knobs and switches. At least in part the user interface may also be provided as a touch sensitive display device.

It is understood, that all elements of the oscilloscope 430 that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope 430 and not necessarily need to be partitioned into the different sections explained above.

The data analysis system of the present invention may for example be provided as an additional function to the post processing element 453. To this end, the post processing element 453 may receive the stored time domain signal from the memory 452 and calculate a Fast Fourier Transform for segments of the stored time domain signal. In embodiments no dedicated data segmentation processor may be required. Instead, the respective segments may directly be read from the memory 452.

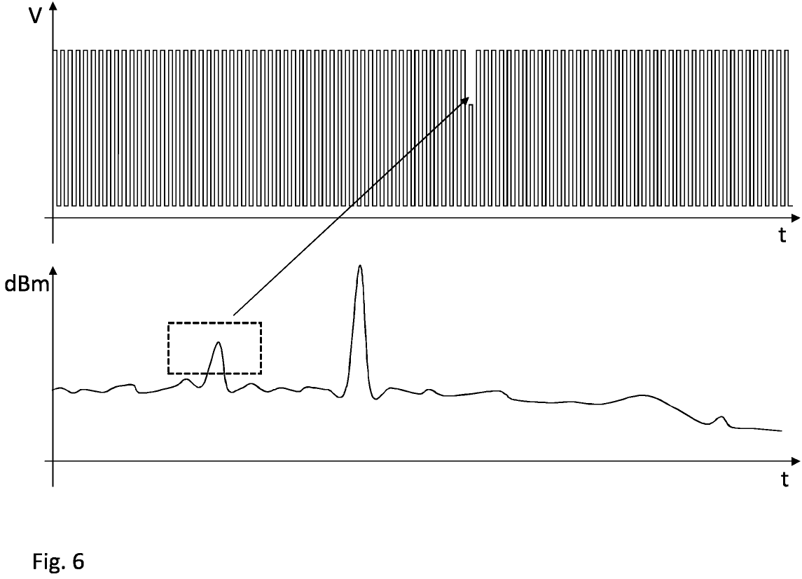

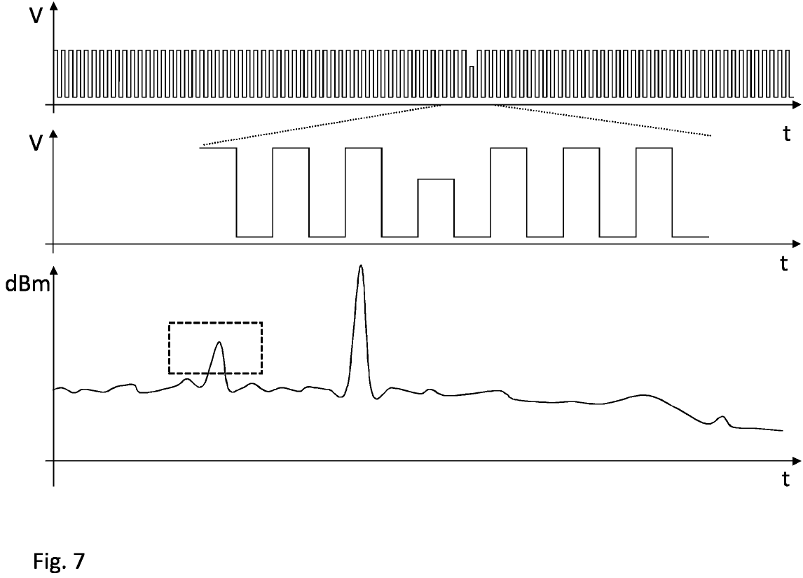

The post processing element 453 may then combine the single calculated single Fast Fourier Transforms into a spectrum waveform. The spectrum waveform and the time domain signal may then be displayed on the display 455 as exemplarily indicated in FIGS. 6 and 7.

After generating the spectrum waveform, the post processing element 453 may also perform the function of the data analyzer and monitor the spectrum waveform for the presence of a data anomaly. If a data anomaly is detected, the post processing element 453 may also identify the segment of the time domain signal that caused the data anomaly in the spectrum waveform and provide the data of the respective segment to the display 455 for displaying to a user e.g., as exemplified in FIGS. 6 and 7.

Of course, the function of the data segmentation processor, the data converter, the data analyzer and the segment identifier may at least in part also be performed by the acquisition processing element 451 if adequate.

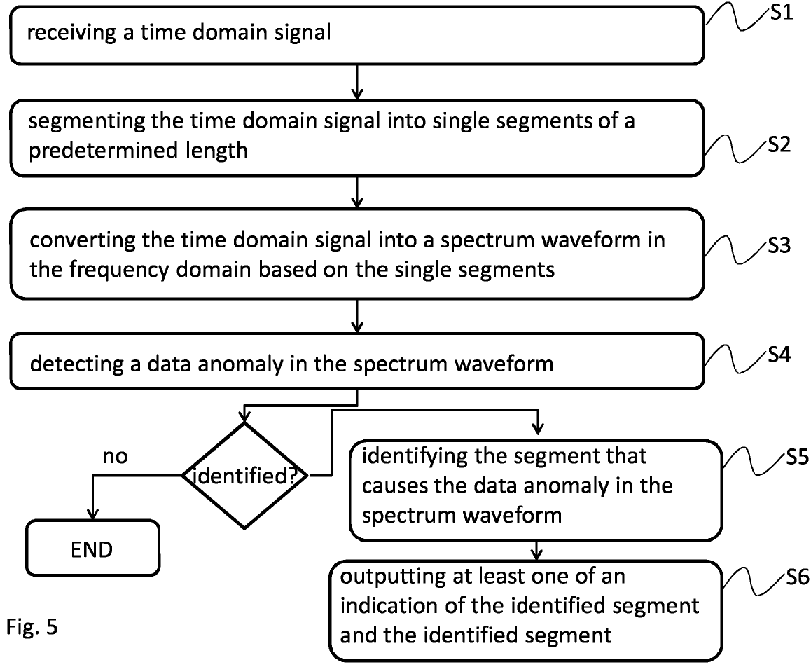

FIG. 5 shows a flow block diagram of an embodiment of a data analysis method.

The data analysis method comprises receiving a time domain signal, S1. The received time domain signal is then segmented, S2, into single segments of a predetermined length and converted, S3, into a spectrum waveform in the frequency domain based on the single segments.

The spectrum waveform is analyzed, S4, for the existence of a data anomaly. If the data anomaly is detected in the spectrum waveform, the segment that causes the data anomaly in the spectrum waveform is identified, S5, and at least one of an indication of the identified segment and the identified segment is output, S6.

The time domain signal may comprise or may be provided as at least one of a real value time series of data points, a signal that is derived from a real value time series of data points, an envelope of a signal in the time domain, a complex value time series of data points, a mathematical derivative of a real value time series of data points, a logarithm of a real value time series of data points, a n-th root of a real value time series of data points, a maximum function of a real value time series of data points, a minimum function of a real value time series of data points, and an average function of a real value time series of data points.

The analysis may, therefore, not only be focused on a measured signal but on any kind of derivative signals that are based on the actually measured signal.

Segmenting, S2, may comprise segmenting the time domain signal such that consecutive ones of the single segments comprise an overlap of a predetermined amount with each other. As explained above, using an overlap between the single segments assures that no signal components are neglected in the analysis.

Of course, the size of the overlap may be adapted to the respective window function that is used in the Fourier Transformation.

Identifying, S4, may further comprise identifying a time stamp of the identified segment. The time stamp may be used to identify or map the section of the time domain signal that causes the anomaly to other signals that also are acquired with time stamps. Such other signals may e.g., be recorded by other measurement devices in the same application.

The process of outputting, S6, may further comprise outputting the time stamp with the at least one of an indication of the identified segment or the identified segment or outputting the time stamp instead of the at least one of an indication of the identified segment or the identified segment.

The data analysis method may also comprise displaying at least one of the time domain signal and the spectrum waveform, and, if the data anomaly is detected in the spectrum waveform, displaying the detected segment as alternative to the time domain signal or in addition to the time domain signal.

Further, the data analysis method may further comprise identifying the source for the anomaly in the respective segment of the time domain signal. The source of the anomaly may be a specific feature in the identified segment that causes the anomaly, like for example a runt signal.

The data analysis method may further comprise automatically defining the anomaly based on an analysis of the spectrum waveform. Such an analysis may comprise at least one of calculating an average value, calculating a mean value, and applying a machine learning algorithm.

FIG. 6 shows a schematic diagram of a time domain signal and a spectrum waveform as it may be shown on the display of the measurement device.

The time domain signal is shown in an upper diagram, wherein voltage is shown over time. The spectrum waveform is shown in a lower diagram, wherein dBm is shown over time.

The time domain signal is exemplarily shown as a square wave signal and comprises a runt signal right of the center of the time axis.

As can be seen in the spectrum waveform, the main frequency of the square wave signal dominates in the frequency domain. However, the runt signal causes a frequency spike left of the dominating frequency.

In real measurement scenarios, the time domain signal is acquired over long period of time and the space on the screen is usually limited, such that the time domain signal is only shown very compressed on the time axis. Therefore, a runt signal may usually not be identified by a user visibly in the time domain signal.

A user may, however, identify the data anomaly in the spectrum waveform and define a respective data anomaly, shown as rectangle in the lower diagram. The user may define this zone for example via a touchscreen of a measurement device or any other input device. The data anomaly may now be detected by the data analysis system through signal components that lay within the defined zone.

FIG. 7 shows another schematic diagram of a time domain signal and a spectrum waveform, wherein the data anomaly is identified and the respective segment of the time domain signal is separately shown magnified along the time axis.

A separate, third diagram is shown between the upper diagram that shows the full time domain signal, and the lower diagram that shows the spectrum waveform with the definition of the data anomaly.

The center diagram now allows a user to easily identify the runt signal in the center of the zoomed-in segment of the time domain signal.

Of course, a time stamp may also be indicated for the runt signal if required by the user.

Although specific embodiments have been illustrated and described herein, it will be appreciated by those of ordinary skill in the art that a variety of alternate and/or equivalent implementations exist. It should be appreciated that the exemplary embodiment or exemplary embodiments are only examples, and are not intended to limit the scope, applicability, or configuration in any way. Rather, the foregoing summary and detailed description will provide those skilled in the art with a convenient road map for implementing at least one exemplary embodiment, it being understood that various changes may be made in the function and arrangement of elements described in an exemplary embodiment without departing from the scope as set forth in the appended claims and their legal equivalents. Generally, this application is intended to cover any adaptations or variations of the specific embodiments discussed herein. Any explanations provided for apparatus or system embodiments may also apply to the method embodiments and vice versa.

LIST OF REFERENCE SIGNS

| | |
|---|---|
| 100, 200, 300 | data analysis system |
| 101, 201 | data input interface |
| 102, 202, 302 | time domain signal |
| 103, 203 | data segmentation processor |
| 104-1 - 104-n, 204-1 - 204-n | segment |
| 105, 205 | data converter |
| 106, 206 | spectrum waveform |
| 107, 207 | data analyzer |
| 108, 208 | data anomaly |
| 109, 209 | segment identifier |
| 110, 210 | data output interface |
| 215 | automatic anomaly identifier |
| 320 | measurement device |
| 321 | measurement interface |
| 322 | acquisition circuitry |
| 323 | time series of data points |
| 324 | generator |
| 325 | display |
| 430 | oscilloscope |
| 431 | vertical system |
| 432 | signal conditioning |
| 433 | attenuator |
| 434 | amplifier |
| 435 | filter |
| 436 | analog-to-digital converter |
| 440 | triggering section |
| 441 | amplifier |
| 442 | filter |
| 443 | trigger system |
| 445 | horizontal system |
| 450 | processing section |
| 451 | acquisition processing element |
| 452 | memory |
| 453 | post processing element |
| 455 | Display |
| S1 - S6 | method steps |

What is claimed is:

1. A data analysis system comprising:
a data input interface for receiving a time domain signal;
a data segmentation processor that segments the time domain signal into single segments of a predetermined length;
a data converter that converts the time domain signal into a spectrum waveform in the frequency domain based on the single segments;
a data analyzer that detects a data anomaly in the spectrum waveform;
a segment identifier that, if the data anomaly is detected in the spectrum waveform, identifies the segment that causes the data anomaly in the spectrum waveform; and
a data output interface that, if the data anomaly is detected in the spectrum waveform, outputs at least one of an indication of the identified segment and the identified segment.

2. A data analysis system according to claim 1, wherein the time domain signal comprises at least one of a real value time series of data points, a signal that is derived from a real value time series of data points, an envelope of a signal in the time domain, a complex value time series of data points, a mathematical derivative of a real value time series of data points, a logarithm of a real value time series of data points, a n-th root of a real value time series of data points, a maximum function of a real value time series of data points, a minimum function of a real value time series of data points, and an average function of a real value time series of data points.

3. A data analysis system according to claim 1, wherein the data segmentation processor segments the time domain signal such that consecutive ones of the single segments comprise an overlap of a predetermined amount with each other.

4. A data analysis system according to claim 1, wherein the data input interface receives a stored time domain signal.

5. A data analysis system according to claim 1, wherein the segment identifier further identifies a time stamp of the identified segment, and wherein the data output interface further outputs the time stamp with the at least one of an indication of the identified segment or the identified segment or outputs the time stamp instead of the at least one of an indication of the identified segment or the identified segment.

6. A data analysis system according to claim 1, comprising a display that displays at least one of the time domain signal and the spectrum waveform.

7. A data analysis system according to claim 6, wherein, if the data anomaly is detected in the spectrum waveform, the display displays the detected segment as alternative to the time domain signal or in addition to the time domain signal.

8. A data analysis system according to claim 1, wherein the segment identifier further identifies the source for the anomaly in the respective segment of the time domain signal.

9. A data analysis system according to claim 1, comprising an automatic anomaly identifier that defines the anomaly based on an analysis of the spectrum waveform, wherein the analysis comprises at least one of calculating an average value, calculating a mean value, and applying a machine learning algorithm.

10. A measurement device comprising:
a measurement interface that measures a time series of data points;
a generator that generates a time domain signal from the time series of data points; and
a data analysis system comprising:
a data input interface for receiving the time domain signal;
a data segmentation processor that segments the time domain signal into single segments of a predetermined length;
a data converter that converts the time domain signal into a spectrum waveform in the frequency domain based on the single segments;
a data analyzer that detects a data anomaly in the spectrum waveform;
a segment identifier that, if the data anomaly is detected in the spectrum waveform, identifies the segment that causes the data anomaly in the spectrum waveform; and
a data output interface that, if the data anomaly is detected in the spectrum waveform, outputs at least one of an indication of the identified segment and the identified segment; and
a display that displays at least one of the time domain signal and the spectrum waveform, and, if the data anomaly is detected in the spectrum waveform, further displays the detected segment as alternative to the time domain signal or in addition to the time domain signal.

11. A measurement device according to claim 10, wherein the time domain signal comprises at least one of a real value time series of data points, a signal that is derived from a real value time series of data points, an envelope of a signal in the time domain, a complex value time series of data points, a mathematical derivative of a real value time series of data points, a logarithm of a real value time series of data points, a n-th root of a real value time series of data points, a maximum function of a real value time series of data points, a minimum function of a real value time series of data points, and an average function of a real value time series of data points.

12. A measurement device according to claim 10, wherein the data segmentation processor segments the time domain signal such that consecutive ones of the single segments comprise an overlap of a predetermined amount with each other.

13. A measurement device according to claim 10, comprising a data memory that stores the time series of data points; and wherein the data input interface receives a time domain signal that is generated based on the stored time series of data points.

14. A measurement device according to claim 10, wherein the segment identifier further identifies a time stamp of the identified segment, and wherein the data output interface further outputs the time stamp with the at least one of an indication of the identified segment or the identified segment or outputs the time stamp instead of the at least one of an indication of the identified segment or the identified segment; and.

15. A data analysis method comprising:
receiving a time domain signal;
segmenting the time domain signal into single segments of a predetermined length;
converting the time domain signal into a spectrum waveform in the frequency domain based on the single segments;
detecting a data anomaly in the spectrum waveform;
if the data anomaly is detected in the spectrum waveform, identifying the segment that causes the data anomaly in the spectrum waveform; and
if the data anomaly is detected in the spectrum waveform, outputting at least one of an indication of the identified segment and the identified segment.

16. A data analysis method according to claim 15, wherein the time domain signal comprises at least one of a real value time series of data points, a signal that is derived from a real value time series of data points, an envelope of a signal in the time domain, a complex value time series of data points, a mathematical derivative of a real value time series of data points, a logarithm of a real value time series of data points, a n-th root of a real value time series of data points, a maximum function of a real value time series of data points, a minimum function of a real value time series of data points, and an average function of a real value time series of data points.

17. A data analysis method according to claim 15, wherein segmenting comprises segmenting the time domain signal such that consecutive ones of the single segments comprise an overlap of a predetermined amount with each other.

18. A data analysis method according to claim 15, wherein identifying further comprises identifying a time stamp of the identified segment, and wherein outputting further comprises outputting the time stamp with the at least one of an indication of the identified segment or the identified segment or outputting the time stamp instead of the at least one of an indication of the identified segment or the identified segment.

19. A data analysis method according to claim 15, comprising displaying at least one of the time domain signal and the spectrum waveform, and, if the data anomaly is detected in the spectrum waveform, displaying the detected segment as alternative to the time domain signal or in addition to the time domain signal.

20. A data analysis method according to claim 15, further comprising identifying the source for the anomaly in the respective segment of the time domain signal.
